(19) United States
(12) Patent Application Publication
(10) Pub. No.: US 2010/0039130 A1
(43) Pub. Date: Feb. 18, 2010

(54) INSPECTING METHOD, INSPECTING APPARATUS AND COMPUTER READABLE STORAGE MEDIUM HAVING PROGRAM STORED THEREIN

(75) Inventors: Yasunori Kumagai, Yamanashi (JP); Ka Toh, Yamanashi (JP)

Correspondence Address: DITTHAVONG MORI & STEINER, P.C., 918 Prince Street, Alexandria, VA, 22314, US

(73) Assignee: Tokyo Electron Limited, Tokyo (JP)

(21) Appl. No.: 12/441,957

(22) PCT Filed: Dec. 21, 2007
(86) PCT No.: PCT/JP2007/074683

§ 371 Date: Mar. 19, 2009

(30) Foreign Application Priority Data
Dec. 27, 2006 (JP) 2006-351581

(51) Int. Cl. G01R 31/02; G01R 1/06

(52) U.S. Cl. 324/754

(57) ABSTRACT

A probe card of an inspecting apparatus is provided with a flitting circuit to cause a flitting by applying voltages to a pair of probes being in contact with an electrode of a substrate to electrically conduct the probes to the substrate, and a switching circuit to electrically connect the probe pair to the flitting circuit to freely switch polarities of the voltages to be applied to the probe pair. The polarities of the voltages to be applied to the probes are changed every time a flitting operation is performed for the electrode of the substrate, so that a trouble of unevenness in quantity of an adhered material on the probes can be eliminated.

### TECHNICAL FIELD

The present invention relates to an inspecting method for inspecting electric characteristics of an inspection object, an inspecting apparatus to execute the inspecting method, and a storage medium having a program stored therein to implement the inspecting method.

### BACKGROUND ART

The electric characteristics of an electron circuit such as an IC and LSI formed on a semiconductor wafer are inspected by use of an inspecting apparatus. The inspecting apparatus has a probe card electrically connected to a tester, and many probes are mounted on a lower surface of the probe card. Thus, the electron circuit is inspected when each electrode of the electron circuit on the wafer is brought in contact with the probe and an electric signal is transmitted to the electrode.

However, in a case where an oxide film is formed on an electrode surface of the wafer, the electric signal is not likely to be transmitted, so that the inspection cannot be correctly performed. In addition, when the probe is pressed against the electrode surface strongly to implement electric conduction, the probe and the electron circuit could be damaged. Therefore, it is proposed, before the inspection, to cause a flitting to cause insulation breakdown on the electrode surface by bringing the electrode in contact with one set of two probes (probe pair) at a low pressure and applying voltages to the probe pair and implement preferable electric conduction between the probe and the electrode (referred to as a “flitting” hereinafter) (refer to Patent Documents 1 and 2). In addition, the flitting means a phenomenon in which when a voltage having high potential gradient is applied to a metal surface on which an oxide film is formed, the oxide film is broken down and a current flows on the metal surface.

### Patent Document 1: Japanese Unexamined Patent Application Publication No. 2002-139542

### Patent Document 2: Japanese Unexamined Patent Application Publication No. 2004-191208

### DISCLOSURE OF THE INVENTION

### Problem to be Solved by the Invention

Meanwhile, when the above flitting operations are performed many times by the inspecting method, dissolved materials of the electrodes are attached to the probe pair gradually. At this time, as shown in FIG. 10, the inventor has confirmed the fact that there is a large difference in adhered quantity between a dissolved material Q on a probe P1 on an anode side and a dissolved material Q on a probe P2 on a cathode side. Thus, when there is a large difference in adhered quantity of the dissolved materials between the probe pair, the conductivity of one probe is lowered at an early stage due to the adhered material, so that the probe pair has short life as a whole. In addition, when tip ends of the probe pair are pressed against an abrasive sheet to remove the adhered material, the probe having a less adhered material is abraded too much. Thus, since the height of the probe pair becomes uneven, the contact between the probe pair and the electrode becomes unstable and the inspection cannot be performed stably.

The present invention has been made in view of the above problems and it is an object of the present invention to eliminate unevenness in the quantity of the adhered materials on probe pair, to elongate the life of the probe pair, and stabilize electric contact between the probe pair and an inspection object.

### Means for Solving the Problem

According to the present invention to achieve the above object, an inspecting method is for inspecting electric characteristics of an inspection object by bringing an electrode of the inspection object in contact with a probe, and has a flitting step of bringing the electrode of the inspection object in contact with a probe pair and applying voltages to the probe pair to cause a flitting and electrically conduct at least one probe to the inspection object, and a polarity changing step of changing polarities of the voltages applied to the probe pair including a set of two probes.

According to the present invention, since the polarity changing step for changing the polarities of the voltages to be applied to the probe pair is provided in addition to the flitting step, the unevenness in the quantity of the adhered materials on the anode side and the cathode side of the probe pair can be eliminated by carrying out the polarity changing step. As a result, the probe pair has a long life and the electric contact between the probe pair and the electrode of the inspection object can be stabilized.

When the flitting step is sequentially performed for the plurality of electrodes of the inspection object, the polarity changing step may be performed every time the flitting step is performed for the electrode, or the polarity changing step may be performed after the flitting steps are performed two or more times.

According to another aspect of the present invention, an inspecting apparatus is to inspect electric characteristics of an inspection object by bringing the electrode of the inspection object in contact with a probe, and has a flitting circuit to cause a flitting by applying voltages to the probe pair including a set of two probes which are in contact with the electrode of the inspection object to electrically conduct at least one probe to the inspection object, and a switching circuit to electrically connect the probe pair to the flitting circuit, and freely switch the polarities of the voltages applied to the probe pair.

In the inspecting apparatus, when a flitting operation is sequentially performed for the plurality of electrodes of the inspection object by the flitting circuit, the polarities of the voltages applied to the probe pair may be changed by the switching circuit every time the flitting operation is performed for the electrode. In addition, when the flitting operation is sequentially performed for the plurality of electrodes of the inspection object by the flitting circuit, the polarities of the voltages applied to the probe pair may be changed by the switching circuit after the flitting operations are performed two or more times.

According to still another aspect of the present invention, to execute an inspecting method by an inspecting apparatus, there is provided a computer readable storage medium having a program stored therein and running on a computer of a control unit to control the inspecting apparatus.

### EFFECT OF THE INVENTION

According to the present invention, since the unevenness in the quantity of the adhered materials generated on the probe pair can be eliminated, the probe pair has a long life, for example.

### BRIEF DESCRIPTION OF THE DRAWING

FIG. 1 is a side view showing an outline of a constitution of an inspecting apparatus.

FIG. 2 is a schematic diagram showing one example of a circuit constitution of a probe card.

FIG. 3 is a flowchart showing an inspecting process.

FIG. 4 is an explanatory diagram showing polarities of a probe pair at the time of flitting operation.

FIG. 5 is a schematic diagram showing a connection example of circuits of the probe card at the time of inspection.

FIG. 6 is a schematic diagram showing a connection example of the circuits of the probe card after changing the polarities of the probe pair.

FIG. 7 is an explanatory diagram showing the polarities of the probe pair at the time of the flitting operation after changing the polarities.

FIG. 8(a) is an experiment photograph showing a state of a tip end of a probe on the anode side and FIG. 8(b) is an experiment photograph showing a state of a tip end of a probe on the cathode side when the flitting operations are performed many times without changing the polarities.

FIG. 9(a) is an experiment photograph showing a state of a tip end of a probe on the anode side and FIG. 9(b) is an experiment photograph showing a state of a tip end of a probe on the cathode side when the flitting operations are performed many times while the polarities are changed alternately.

FIG. 10 is an explanatory view schematically showing the adhesive quantity of dissolved materials adhered onto a probe on the cathode side and onto a probe on the anode side.

### EXPLANATION OF SYMBOLS

1 inspecting apparatus
2 probe card
10a, 10b probe
40 inspecting circuit
41 flitting circuit
43 second switching circuit
P1, P2, P3 electrode
W wafer

### DESCRIPTION OF THE PREFERRED EMBODIMENTS

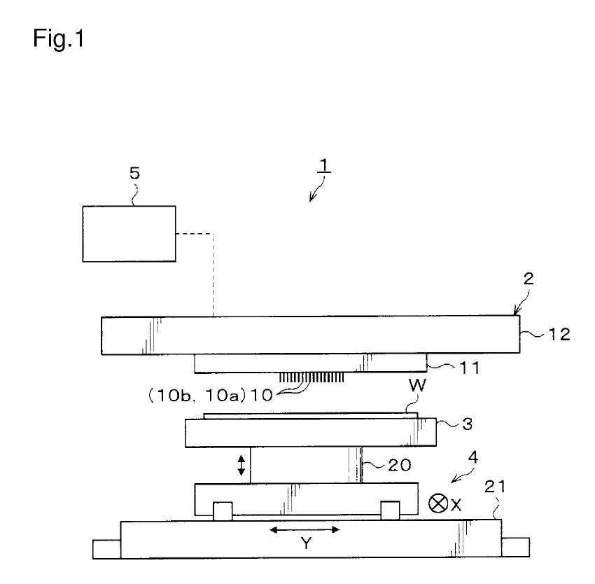

A preferred embodiment of the present invention will be described hereinafter. FIG. 1 is an explanatory view showing a constitution of an inspecting apparatus 1 according to an embodiment of the present invention.

The inspecting apparatus 1 is, for example, provided with a probe card 2, a chuck 3 to suck and retain a wafer W as an inspecting object, a moving mechanism 4 to move the chuck 3, and a tester 5.

For example, the probe card 2 includes a contactor 11 to support a plurality of probes 10 on its lower surface, and a printed-wiring substrate 12 mounted on an upper surface of the contactor 11. Each probe 10 is electrically connected to the printed-wiring substrate 12 through the body of the contactor 11. The tester 5 is electrically connected to the probe card 2, and the operation of the probe card 2 can be controlled by an electric signal from the tester 5. A circuit constitution of the probe card 2 will be described below.

The chuck 3 is roughly in the form of a disk having a horizontal upper surface. A suction port (not shown) is provided in the upper surface of the chuck 3, and the wafer W can be sucked and retained on the chuck 3 by suction from the suction port.

The moving mechanism 4 is provided with an elevator driving unit 20 such as a cylinder to elevate the chuck 3, and an X-Y stage 21 on which the elevator driving unit 20 is moved in two horizontal directions (X direction and Y direction) crossing perpendicularly. Thus, the wafer W retained by the chuck 3 is moved in three dimensions and an electrode of the surface of the wafer W can be brought in touch with the probe 10.

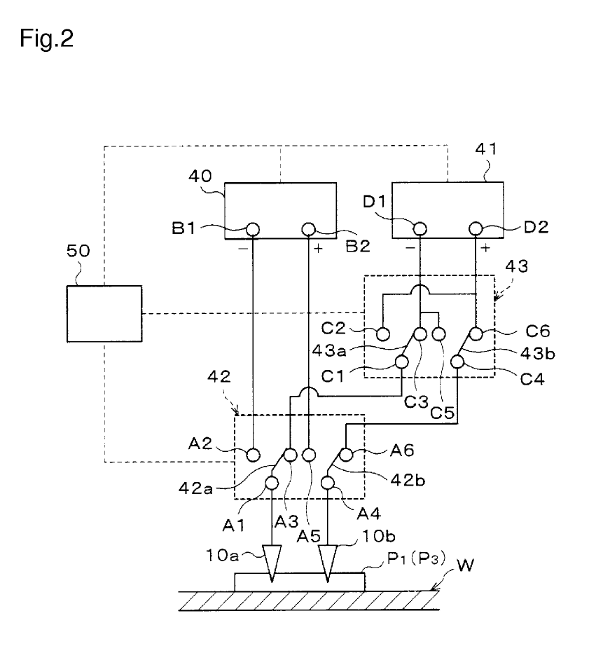

For example, as shown in FIG. 2, the probe card 2 includes an inspecting circuit 40 for transmitting and receiving an electric signal to and from a pair of probes 10a and 10b to inspect electric characteristics, a flitting circuit 41 for generating a flitting by applying a voltage to the probe pair 10a and 10b, a first switching circuit 42 for switching between connections of the inspecting circuit 40 and the flitting circuit 41 to the probe pair 10a and 10b, and a second switching circuit 43 for switching between polarities of the voltages applied from the flitting circuit 41 to the probe pair 10a and 10b.

The first switching circuit 42 includes a switching element 42a switching between connection of a terminal A1 connected to the probe 10a to a terminal A2 connected to a cathode terminal B1 of the inspecting circuit 40, and connection of the terminal A1 to a terminal A3 connected to a cathode terminal D1 or an anode terminal D2 of the flitting circuit 41. In addition, the first switching circuit 42 includes a switching element 42b switching between connection of a terminal A4 connected to the probe 10b to a terminal A5 connected to an anode terminal B2 of the inspecting circuit 40, and connection of the terminal A4 to a terminal A6 connected to the cathode terminal D1 or the anode terminal D2 of the flitting circuit 41.

The second switching circuit 43 includes a switching element 43a switching between connection of a terminal C1 connected to the terminal A3 of the first switching circuit 42 to a terminal C2 connected to the anode terminal D2 of the flitting circuit 41, and connection of the terminal C1 to a circuit C3 connected to the cathode terminal D1 of the flitting circuit 41. In addition, the second switching circuit 43 includes a switching element 43b switching between connection of a terminal C4 connected to a terminal A6 of the first switching circuit 42 to a terminal C5 connected to the cathode terminal D1 of the flitting circuit, and connection of the terminal C4 to a terminal C6 connected to the anode terminal D2 of the flitting circuit 41.

The tester 5 is provided with a control unit 50 for controlling operations of the inspecting circuit 40, the flitting circuit 41, the first switching circuit 42, and the second switching circuit 43. The control unit 50 is composed of a computer including a CPU and a memory, and can implement an inspecting process in the inspecting apparatus 1 by executing a program stored in the memory. In addition, the various programs to implement the inspecting process in the inspecting apparatus 1 are stored in a computer readable storage medium such as a CD, and they are installed from the storage medium into the control unit 50 to be used.

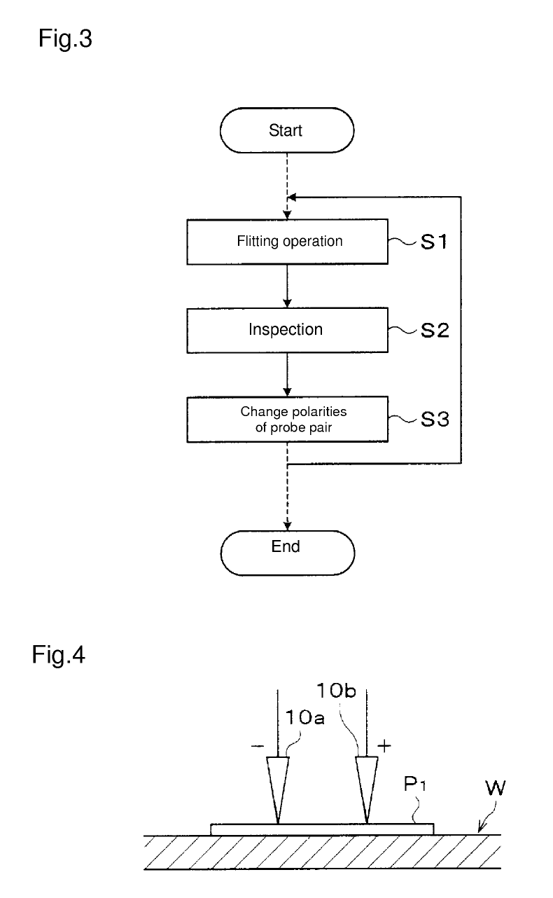

Next, a description will be made of the inspecting process performed in the inspecting apparatus 1 constituted as described above to inspect the electric characteristics of the wafer W. FIG. 3 is a flowchart of the inspecting process in this embodiment.

First, as shown in FIG. 1, the wafer W is sucked and retained on the chuck 3. Then, the wafer W on the chuck 3 is lifted by the moving mechanism 4, and as shown in FIG. 2, an electrode P1 on the wafer W is brought in contact with the probe pair 10a and 10b.

At this time, the flitting circuit 41 and the probe pair 10a and 10b are electrically connected by the first switching circuit 42. For example, the cathode terminal D1 of the flitting circuit 41 is connected to the probe 10a, and the anode terminal D2 of the flitting circuit 41 is connected to the probe 10b by the second switching circuit 43.

Thus, for example, as shown in FIG. 4, voltages having potential gradient of about 10⁵ to 10⁶V/cm are applied from the flitting circuit 41 to the probe pair 10a and 10b so that the probe 10a becomes a cathode and the probe 10b becomes an anode. Thus, the flitting is generated and an oxide film on the surface of the electrode P1 is broken down, so that the probe pair 10a and 10b is electrically conducted to the electrode P1, whereby a flitting step S1 (shown in FIG. 3) is performed.

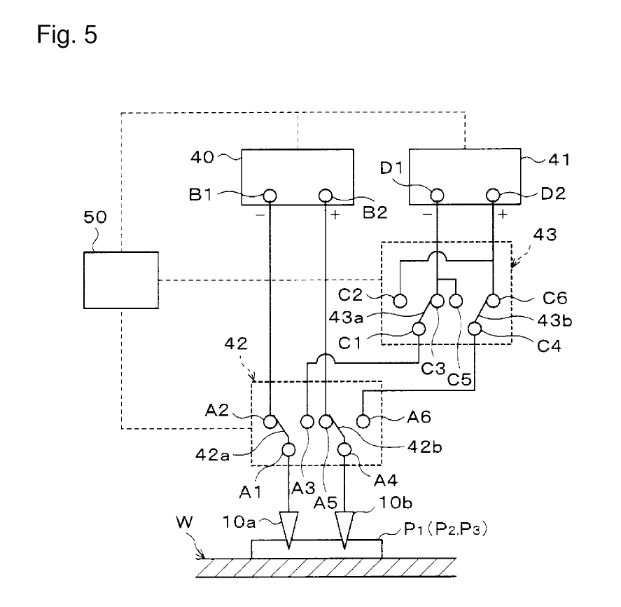

When the flitting step S1 for the electrode P1 is completed, as shown in FIG. 5, the inspecting circuit 40 and the probe pair 10a and 10b are electrically connected by the fist switching circuit 42. Then, an inspecting electric signal is applied from the inspecting circuit 40 to the electrode P1 through the probe pair 10a and 10b, whereby electric characteristics of an electron circuit having the electrode P1 are inspected (step S2 in FIG. 3).

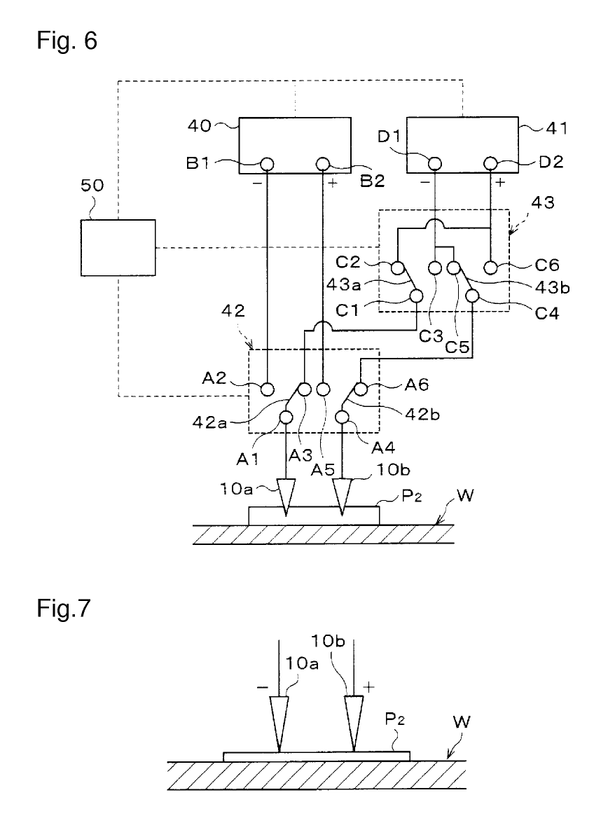

When the inspection of the electron circuit of the electrode P1 is completed, the wafer W on the chuck 3 is moved by the moving mechanism 4, and as shown in FIG. 6, a next electrode P2 on the wafer W is brought in contact with the probe pair 10a and 10b.

At this time, the flitting circuit 41 and the probe pair 10a and 10b are electrically connected by the first switching circuit 42. The anode terminal D2 of the flitting circuit 41 is connected to the probe 10a, and the cathode terminal D1 of the flitting circuit 41 is connected to the probe 10b by the second switching circuit 43, whereby voltage polarities applied to the probe pair 10a and 10b are changed (step S3 in FIG. 3).

Thus, as shown in FIG. 7, the voltages having polarities opposite to those to the electrode P1 in the flitting step S1 are applied from the flitting circuit 41 to the probe pair 10a and 10b so that the probe 10a becomes the anode and the probe 10b becomes the cathode. Thus, the flitting is generated and the probe pair 10a and 10b and the electrode P2 are electrically conducted, whereby the flitting step S1 is performed.

When the flitting step S1 for the electrode P2 is completed, as shown in FIG. 5, the inspecting circuit 40 and the probe pair 10a and 10b are electrically connected by the first switching circuit 42. The inspecting electric signal is sent to the electrode P2 from the inspecting circuit 40 through the probe pair 10a and 10b and the electric characteristics of an electron circuit having the electrode P2 is inspected (step S2 in FIG. 3).

When the inspection for the electron circuit of the electrode P2 is completed, the wafer W on the chuck 3 is moved by the moving mechanism 4 again, and as shown in FIG. 2, an electrode P3 on the wafer W is brought in touch with the probe pair 10a and 10b. Then, the polarities of the voltages to be applied from the flitting circuit 41 to the probe pair 10a and 10b are changed by the second switching circuit 43 (step S3 in FIG. 3).

Then, the voltages having the polarities opposite to those to the electrode P2 in the previous flitting step S1 are applied to the probe pair 10a and 10b and the flitting step S1 is performed, and then the electric characteristics of an electron circuit having the electrode P3 are inspected (step S2 in FIG. 3). Then, when the next electrode is inspected, the polarities of the voltages to be applied to the probe pair 10a and 10b are changed at the time of flitting operation (step S3 in FIG. 3).

Thus, the flitting step S1, the inspecting step S2, and the polarity changing step S3 for the probe pair 10a and 10b are repeatedly performed for the plurality of electrodes on the wafer W, and every time the flitting operation is performed for the electrode, the polarities of the voltages applied to the probe pair 10a and 10b are changed.

After inspecting the electric characteristics of the electron circuits of all the electrodes on the wafer W, the chuck 3 is lowered and the wafer W is removed from the chuck 3 and a series of inspecting process are completed.

According to this embodiment, in the plurality of flitting steps S1 for the plurality of electrodes, since the polarities of the voltages applied to the probe pair 10a and 10b are alternately changed, dissolved materials of the electrodes can be uniformly attached to the probe pair 10a and 10b. This effect will be examined hereinafter.

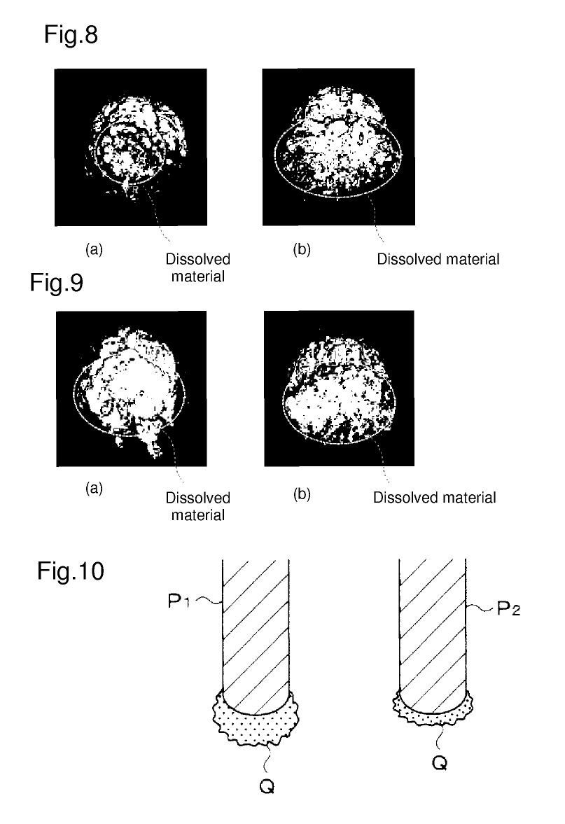

FIG. 8 shows a state of a tip end of a probe on the anode side (FIG. 8 (a)) and a state of a tip end of a probe on the cathode side (FIG. 8(b)) when the flitting operations are performed 2000 times without changing the polarities. FIG. 9 shows a state of a tip end of a probe on the anode side (FIG. 9(a)) and a state of a tip end of a probe on the cathode side (FIG. 9(b)) when the flitting operations are performed 2000 times while the polarities are changed alternately. In this experiment, an aluminum electrode is brought in contact with a probe formed of Pd (palladium) in the flitting operations.

As shown in FIG. 8, in the case where the flitting operations are repeated without changing the polarities, a lot of dissolved aluminum is attached to the probe on the cathode side as compared with the probe on the anode side, and the quantity of adhered materials are different between the probes. Meanwhile, as shown in FIG. 9, in the case where the flitting operations are repeated while the polarities are changed alternately, the adhered quantity of the dissolved aluminum on the probe on the cathode side is almost the same as that on the probe on the anode side, so that the problem of the unevenness in quantity of the adhered materials between the probes is solved. In addition, the electrode having the more dissolved adhered material and conductivity between the cathode and the anode depend on the combination of an electrode material and a probe material.

As shown by the experiment result, when the polarities of the voltages applied to the probe pair 10a and 10b are changed every flitting operation according to this embodiment, the problem of unevenness in quantity of adhered materials between the probe pair 10a and 10b can be solved. As a result, since the electrode material can be uniformly attached to the probe pair 10a and 10b, and the probes can be used many times until the conductivity of either probe is damaged due to the adhered materials, the probe pair 10a and 10b have a long life. In addition, since the quantity of the adhered materials of the probe pair 10a and 10b can be almost the same, when the adhered materials of the probe pair 10a and 10b are removed by pressing the probe pair 10a and 10b against an abrasive sheet, one side probe is not abraded too much. As a result, the height of the probe pair 10a and 10b due to the adhered materials can be even, so that the contact between the probe pair 10a and 10b and the electrode can be stabilized.

Although the preferred embodiment of the present invention has been described with reference to the drawings in the above, the present invention is not limited to the above-illustrated embodiments. It is clearly understood by those skilled in the art that various kinds of modifications and variations may be added to the illustrated embodiments within the same or equal scope of the appended claims and belong to the technical range of the present invention.

According to the above embodiment, the flitting step S1, the inspecting step S2, and the polarity changing step S3 for the probe pair 10a and 10b are performed repeatedly and every time the flitting operation is performed for the electrode, the polarities of the voltages applied to the probe pair 10a and 10b are changed. In other words, every time the electrode on the wafer W to be inspected is changed, the polarities are changed and then the flitting step is performed and the inspecting step is performed. However, it is not always necessary to change the polarities every time the electrode to be inspected is changed, and as another case, the polarity changing step may be performed only after the plurality of flitting steps have been performed with the same polarity.

For example, after the flitting step is performed and then the inspecting step is performed, even when the electrode to be inspected is changed, the flitting step and the inspecting step may be performed with the same polarity until a predetermined number of inspecting operations is counted. Thus, only after the predetermined number of inspecting operations is counted, the polarity changing step for the probe pair 10a and 10b is to be performed. Then, even when the electrode to be inspected is changed, the flitting step and the inspecting step may be continuously performed with the same polarity until the predetermined inspection number is reached again. Thus, the number of polarity changing steps can be reduced and the inspecting process can be performed at high speed.

In addition, according to the above predetermined number, the allowable number not requiring the change of the polarities is predetermined by performing the flitting step and the inspecting step repeatedly without changing the polarities and checking the adhered quantity of the dissolved material onto each probe to confirm an allowable adhered quantity and an uneven degree of the adhered material while the polarities are not changed, and based on the allowable number, the above predetermined number is determined.

As another case, an H bridge circuit is used for the switching circuit 43 of the inspecting apparatus 1 described in the above embodiment. The object to be inspected by the inspecting apparatus 1 described in the above embodiment may be a substrate such as a FPD (Flat Panel Display) other than the wafer W.

### INDUSTRIAL APPLICABILITY

The present invention is useful in eliminating the unevenness in quantity of the adhered materials on the probe pair.

1. An inspecting method for inspecting electric characteristics of an inspection object by bringing an electrode of the inspection object in contact with a probe, the inspecting method comprising:
a flitting step of bringing the electrode of the inspection object in contact with a probe pair including a set of two probes and applying voltages to the probe pair to cause a flitting and electrical conduction between at least one probe and the inspection object; and
a polarity changing step of changing polarities of the voltages applied to the probe pair.

2. The inspecting method according to claim 1,
wherein the flitting step is sequentially performed for a plurality of the electrodes of the inspection object, and the polarity changing step is performed every time the flitting step is performed for the electrode.

3. The inspecting method according to claim 1,
wherein the flitting step is sequentially performed for a plurality of the electrodes of the inspection object, and the polarity changing step is performed after the flitting steps are performed two or more times.

4. An inspecting apparatus to inspect electric characteristics of an inspection object by bringing an electrode of the inspection object in contact with a probe, the inspecting apparatus comprising:
a flitting circuit to cause a flitting by applying voltages to a probe pair including a set of two probes which are in contact with the electrode of the inspection object and electrical conduction between at least one probe and the inspection object; and
a switching circuit to electrically connect the probe pair to the flitting circuit, and arbitrarily switch the polarities of the voltages applied to the probe pair.

5. The inspecting apparatus according to claim 4,
wherein the flitting is sequentially performed for a plurality of the electrodes of the inspection object by the flitting circuit, and
wherein the polarities of the voltages applied to the probe pair are changed by the switching circuit every time the flitting operation is performed for the electrode.

6. The inspecting apparatus according to claim 4,
wherein the flitting is sequentially performed for a plurality of the electrodes of the inspection object by the flitting circuit, and
wherein the polarities of the voltages applied to the probe pair are changed by the switching circuit after the flitting is performed two or more times.

7. A computer readable storage medium storing a program running on a computer of a control unit to control an inspecting apparatus by which an inspecting method is performed,
wherein the inspecting method is for inspecting electric characteristics of an inspection object by bringing an electrode of the inspection object in contact with a probe, and
wherein the inspecting method comprises a flitting step of bringing the electrode of the inspection object in contact with a probe pair including a set of two probes and applying voltages to the probe pair to cause a flitting and electrical conduction between at least one probe and the inspection object; and
a polarity changing step of changing polarities of the voltages applied to the probe pair.

8. The computer readable storage medium storing the program according to claim 7,
wherein the flitting step is sequentially performed for a plurality of the electrodes on the inspection object, and the polarity changing step is performed every time the flitting step is performed for the electrode.

9. The computer readable storage medium storing the program according to claim 7,
wherein the flitting step is sequentially performed for a plurality of the electrodes of the inspection object, and
the polarity changing step is performed after the flitting step is performed two or more times.
